(19) United States
(12) Patent Application Publication
(10) Pub. No.: US 2007/0035014 A1
(43) Pub. Date: Feb. 15, 2007

(54) Method and circuit for reducing series inductance of a decoupling capacitor in a ball grid array (BGA)

(76) Inventor: Patrick Ying Cheung Fung, Sacramento, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/204,866

(22) Filed: Aug. 15, 2005

(51) Int. Cl. H01L 23/16

(52) U.S. Cl. 257/723

(57) ABSTRACT

A method reduces a value of an inductance in series with a decoupling capacitor for a ball grid array. The ball grid array includes a plurality of conductive balls coupled to conductive interconnects exposed on a surface of a circuit board. The surface includes a periphery and an interior and has conductive interconnects exposed on both the interior and the periphery. The method includes physically positioning at least one decoupling capacitor adjacent conductive interconnects on the interior of the surface of the circuit board and electrically coupling each capacitor to at least two of the adjacent conductive interconnects.

### BACKGROUND OF THE INVENTION

Numerous types of electronic devices are commonplace and are utilized by people for a variety of functions in their everyday life. At the heart of many of these devices are integrated circuits or chips that contain electronic circuitry designed to perform required functions. For example, many modern electronic devices include a microprocessor or a digital signal processor, both of which are examples of integrated circuits or chips. A chip includes a semiconductor die in which the electronic circuitry is formed. The semiconductor die is physically mounted to a package including a number of electrical leads. In addition to being physically mounted to the package, the electronic circuitry in the semiconductor die is electrically coupled to the electrical leads of the package. The electronic circuitry formed on the semiconductor die may in this way be coupled through the package and electrical leads to the electronic circuitry of other chips.

One popular type of package for chips is known as a ball grid array (BGA), which is illustrated in the simplified cross-sectional view shown in FIG. 1. A sample chip 100 illustrated in FIG. 1 includes a semiconductor die 102 glued or otherwise physically attached to a top surface of an interconnect board 104. The interconnect board 104 is like a miniature circuit board and includes a number of conductive traces (not shown) to which the electronic circuitry (not shown) in the semiconductor die 102 is connected. These conductive traces in the interconnect board 104 are coupled to conductive balls 106, such as solder balls, which are exposed on a bottom surface of the interconnect board, to electrically interconnect the electronic circuitry in the die 102 to other chips. The chip 100 is typically mounted on an external circuit board 108 via the conductive balls 106 and in this way the electronic circuitry in the die 102 is interconnected with the electronic circuitry of other chips also mounted on the external circuit board. Typically, the chip 100 is connected to a top surface of the external circuit board 108 through flow soldering, which is a process by which the conductive balls 106 are melted to provide the physical and electrical interconnection between external circuit board and the chip. The interconnect board 104 and conductive balls 106 collectively form the “package” of the chip 100 and may be referred to as such in the following description.

FIG. 2 is a bottom view of the external circuit board 108 of FIG. 1 illustrating a number of conductive interconnections 206 arranged in rows and columns on a bottom surface of the external circuit board. The conductive interconnections 206 provide the physical and electrical interconnection points between the conductive balls 106 (FIG. 1) and points in the external printed circuit board. For example, the conductive interconnections 206 may correspond to vias on the external circuit board 108, and during flow soldering each conductive ball 106 (FIG. 1) melts to thereby flow into a corresponding via and interconnect a respective conductive ball and to a point in the external circuit board defined by the via.

Also positioned on the bottom surface of the interconnect board 108 are a number of decoupling capacitors C. Each decoupling capacitor C is electrically interconnected through conductive traces 200a and 200b in the board 108 to a pair of conductive interconnections 206, as illustrated for one capacitor C in the figure. As will be appreciated by those skilled in the art, decoupling capacitors C effectively function as a filter by providing a high frequency short to ground for transients and other high frequency signals that may occur on or be coupled to a supply voltage of the chip 100. Each decoupling capacitor C is coupled between a power supply plane and a ground plane of the chip 100, with multiple capacitors being used at various physical locations for each power supply plane for better filtering. Some of the conductive interconnections 206 are coupled to the power supply plane and some to the ground plane of the chip 100. Thus, the decoupling capacitors C are coupled through the traces 200a and 200b to selected conductive interconnections 206 and thereby coupled to the supply and ground planes of the chip 100.

As shown in FIG. 2, some of these conductive interconnections 206 lie on the interior of the bottom surface of board 108. Interconnection of a decoupling capacitor C to conductive interconnections 108 on the interior of the bottom surface results in relatively long conductive traces 200a and 220b running between the capacitor and the conductive interconnections. These long conductive traces 200a and 200b have relatively large inductances, which result in a relatively large inductance being formed in series with the corresponding decoupling capacitor C. This relatively large series inductance results in an effective impedance presented by the series connected capacitor C and inductances of traces 200a and 200b that is not as small as desired at a given high frequency. This may result in high frequency transient or other signals on the power supply plane with amplitudes great enough to affect the proper operation of the chip 100. While larger decoupling capacitors C may be used to lower the effective impedance presented by the capacitor and inductances of the traces 200a and 200b, such capacitors are more expensive and occupy more space on the surface of the board 108.

There is a need for reducing the inductance inherently formed in series with decoupling capacitors for a ball grid array chip to improve the decoupling function of the decoupling capacitors.

### SUMMARY OF THE INVENTION

According to one aspect of the present invention, a method reduces a value of an inductance in series with a decoupling capacitor for a ball grid array. The ball grid array includes a plurality of conductive balls coupled to conductive interconnects exposed on a surface of a circuit board. The surface includes a periphery and an interior and has conductive interconnects exposed on both the interior and the periphery. The method includes physically positioning at least one decoupling capacitor adjacent conductive interconnects on the interior of the surface of the circuit board and electrically coupling each capacitor to at least two of the adjacent conductive interconnects.

### BRIEF DESCRIPTION OF THE DRAWINGS

FIG. 1 is a simplified cross-sectional view of a conventional chip including a ball grid array (BGA) package mounted on an external circuit board.

FIG. 2 is a bottom view of the external circuit board of FIG. 1 illustrating a typical arrangement decoupling capacitors and of the physical and electrical interconnections between the chip and the circuit board.

FIG. 3 is bottom view illustrating the arrangement of interior-mounted decoupling capacitors on an external circuit board coupled to ball grid array chip according to one embodiment of the present invention.

FIG. 4 is a more detailed bottom view illustrating the arrangement of interior-mounted decoupling capacitors on the external circuit board of FIG. 3 according to one embodiment of the present invention.

FIG. 5 is a more detailed bottom view illustrating the arrangement of interior-mounted decoupling capacitors on the external circuit board of FIG. 3 according to another embodiment of the present invention.

FIG. 6 is a functional block diagram of a computer system including computer circuitry containing the chip of FIG. 3 according to another embodiment of the present invention.

### DETAILED DESCRIPTION OF PREFERRED EMBODIMENTS

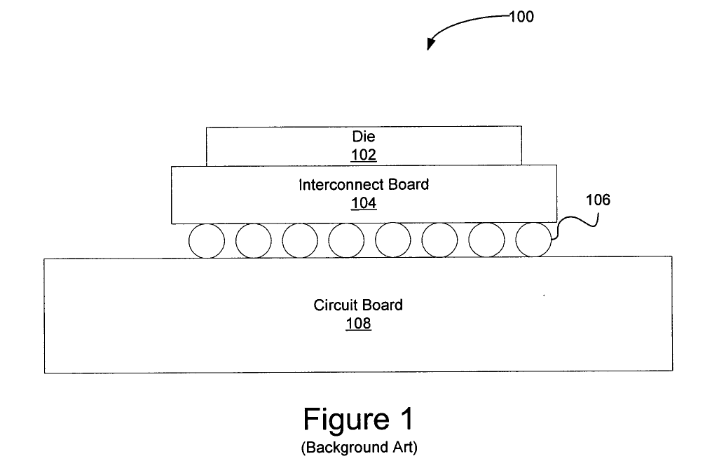

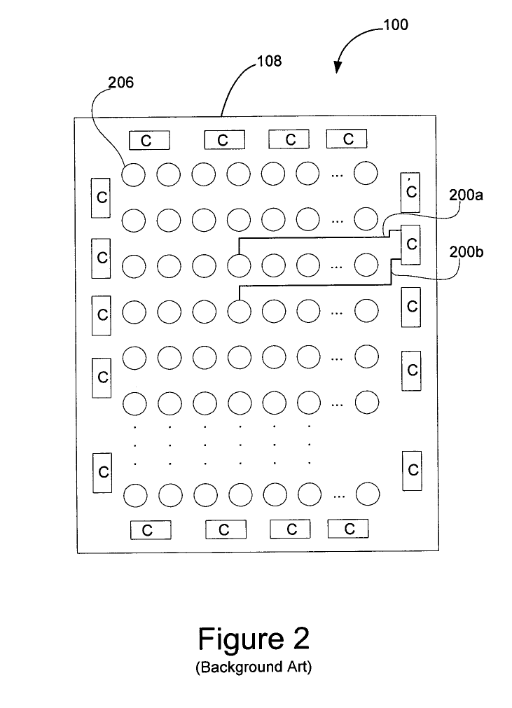

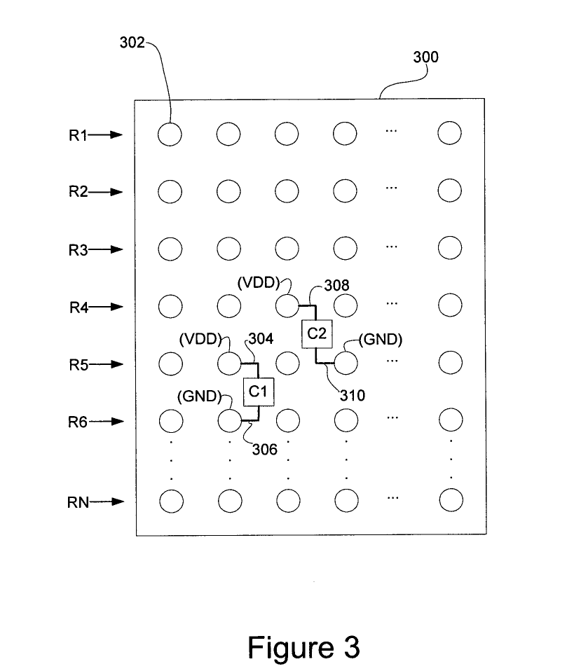

FIG. 3 is bottom view illustrating the arrangement of interior-mounted decoupling capacitors C1 and C2 on an external circuit board 300 coupled to ball grid array chip (not shown) according to one embodiment of the present invention. A number of conductive interconnects 302 are arranged in rows and columns on a bottom surface of the external circuit board. The external circuit board 300 and conductive interconnects 302 are the same as the corresponding components previously discussed with reference to FIGS. 1 and 2 and thus, for the sake of brevity, will not again be described in detail. In contrast to the conventional chip 100 of FIGS. 1 and 2, the embodiment of FIG. 3 includes decoupling capacitors C1 and C2 located not around the periphery of the external circuit board 300 but instead located in the interior of the board and adjacent to conductive interconnects 302 to which the capacitors are electrically coupled, as will be explained in more detail below. Positioning the decoupling capacitors C1 and C2 on the interior of the external circuit board 304 and adjacent the conductive interconnects 302 to which the capacitors are electrically coupled reduces the lengths of conductive traces interconnecting the capacitors and the conductive interconnects. These reduced lengths lower the inductances of the conductive traces, which lowers the overall impedance presented by the decoupling capacitors C1 and C2 and the conductive traces. This lower overall impedance improves the decoupling operation or filtering function of the decoupling capacitors C1 and C2.

In the following description, certain details are set forth in conjunction with the described embodiments of the present invention to provide a sufficient understanding of the invention. One skilled in the art will appreciate, however, that the invention may be practiced without these particular details. Furthermore, one skilled in the art will appreciate that the example embodiments described below do not limit the scope of the present invention, and will also understand that various modifications, equivalents, and combinations of the disclosed embodiments and components of such embodiments are within the scope of the present invention. Embodiments including fewer than all the components of any of the respective described embodiments may also be within the scope of the present invention although not expressly described in detail below. Moreover, in the description that follows, it is understood that the figures related to the various embodiments are not to be interpreted as conveying any specific or relative physical dimensions, and that specific or relative physical dimensions, if stated, are not to be considered limiting unless the claims expressly state otherwise. Further, examples of the various embodiments when presented by way of illustrative examples are intended only to further illustrate certain details of the various embodiments, and should not be interpreted as limiting the scope of the invention. Finally, the operation of well known components and/or processes has not been shown or described in detail below to avoid unnecessarily obscuring the present invention.

In the example of FIG. 3, the decoupling capacitors C1 and C2 are positioned on the interior of the external circuit board 300 between adjacent rows of conductive interconnects 302. The rows of conductive interconnects 302 are designated R1-RN going from top to bottom in the example of FIG. 3. The decoupling capacitor C1 is positioned between conductive interconnects 302 in adjacent rows R5 and R6 while the decoupling capacitor C2 is positioned between conductive interconnects in adjacent rows R4 and R5. A first electrical terminal of the decoupling capacitor C1 is coupled through a first conductive trace 304 to the conductive interconnect 302 in the row R5, which is coupled to a power supply plane VDD of the chip 300 as indicated by the designation (VDD) for this conductive interconnect. A second electrical terminal of the decoupling capacitor C1 is coupled through a second conductive trace 306 to the conductive interconnect 302 in the row R6. This conductive interconnect 302 is coupled to a ground plane GND of the circuit board 300 as indicated by the designation (GND) for this conductive interconnect.

By positioning the decoupling capacitor C1 between the rows R5 and R6 and on the interior of the interconnect board 304 adjacent the conductive interconnects (VDD) and (GND) the lengths and thus the inductances of the conductive traces 304 and 306 are reduced. As a result, at a given frequency the overall impedance presented by the series connected decoupling capacitor C1 and inductance of the traces 304 and 306 is reduced, which provides better filtering of unwanted high-frequency signals on the power supply plane VDD. Note that because the effective inductance of the conductive traces 304 and 306 has been reduced, a smaller value for the decoupling capacitor C1 may be utilized to obtain a desired overall impedance at a given frequency, as will be appreciated by those skilled in the art. If the value of the decoupling capacitor C1 is the same as the values of the decoupling capacitors C in the conventional chip 100 of FIG. 2, then at a given frequency the overall impedance is lower in the embodiment of FIG. 3.

In the example of FIG. 3, note that the decoupling capacitor C2 is positioned between rows R4 and R5 of conductive interconnects 302 and is electrically coupled through conductive traces 308 and 310 to conductive interconnects designated (VDD) and (GND), respectively, in these two rows but in adjacent columns. As a result, the length of the conductive traces 308 and 310 is slightly longer than the lengths of the conductive traces 304 and 306 for the decoupling capacitor C1 where the conductive interconnects designated (VDD) and (GND) are in the same column. In this situation, the decoupling capacitor C2 may be rotated to reduce the lengths of the conductive traces 308 and 310 and thereby reduce the overall impedance presented by this decoupling capacitor in the serious inductance of these traces, as will be explained in more detail below.

Before discussing another embodiment of the present invention, it should be specifically noted that in the embodiment of FIG. 3 the external circuit board 300 would typically contain many more rows and columns of conductive interconnects 302 than is illustrated in the figure. As a result, the lengths of conductive traces running between decoupling capacitors positioned around the periphery of the external circuit board 300 and conductive interconnects 302 on the interior of this board would be much greater than the lengths of such conductive traces when the decoupling capacitors are positioned on the interior of the external circuit board adjacent corresponding conductive interconnects. Also, it should be noted that only two decoupling capacitors C1 and C2 are illustrated merely for ease of description, and typically many more such capacitors would typically be contained on the external circuit 300. Finally, although the decoupling capacitors C1 and C2 are shown and described as being coupled between the power supply plane VDD and ground plane GND, the capacitors could be coupled between other power and reference planes in the circuit board 300, such as between a power supply plane VSS and the ground plane GND, for example. Also note that each decoupling capacitor C1 and C2 may be physically attached to the external circuit board 300, such as being glued, in addition to being connected through the electrical connections to the adjacent conductive interconnects 302.

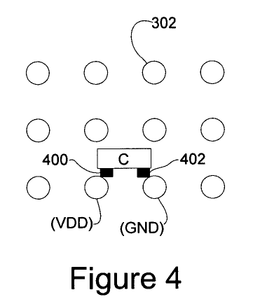

FIG. 4 is a more detailed bottom view of the external circuit board 300 of FIG. 3 showing the positioning of an interior-mounted decoupling capacitor C relative to adjacent conductive interconnects 302 according to one embodiment of the present invention. In this example, the decoupling capacitor C has two electrical terminals 400 and 402 on one side of the capacitor. The electrical terminal 400 is coupled to a first conductive interconnect designated (VDD) corresponding to the power supply plane VDD of the chip (not shown) coupled to the external circuit board 300. Similarly, the electrical terminal 402 is coupled to a second conductive interconnect designated (GND) corresponding to ground plane VDD of the chip (not shown). Both conductive interconnects (VDD) and (GND) are in the same row in the example of FIG. 4, and in this situation the capacitor C may be oriented as shown to reduce the lengths of conductive traces (not shown) between the electrical terminals of the capacitor and these conductive interconnects.

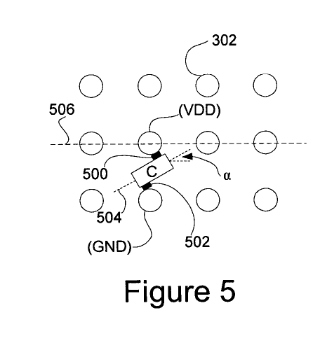

FIG. 5 is a more detailed bottom view of the external circuit board 300 of FIG. 3 showing the positioning of an interior mounted decoupling capacitor C relative to adjacent conductive interconnects 302 according to another embodiment of the present invention. In this example, the decoupling capacitor C has two electrical terminals 500 and 502 on opposite ends of opposing sides of the capacitor. The electrical terminal 500 is coupled to a first conductive interconnect 302 designated (VDD) corresponding to the power supply plane VDD of the associated chip (not shown) and the electrical terminal 502 is coupled to a second conductive interconnect designated (GND) corresponding to ground plane VDD of the chip. The conductive interconnects (VDD) and (GND) are in the same column and adjacent rows in the example of FIG. 5.

In this embodiment, each decoupling capacitor C has a longitudinal or elongated axis 504 that is positioned at an angle α relative to axes 506 defined by each of the rows of conductive interconnects 302. Depending upon the exact physical size of the decoupling capacitor C and the spacing between the conductive interconnects 302, the angle α may be varied to minimize the lengths of conductive traces (not shown) between the electrical terminals 500 and 502 and the corresponding conductive interconnects (VDD) and (GND), respectively.

In another embodiment, the decoupling capacitor C is positioned in an analogous way between conductive interconnects 302 in adjacent columns. Note that this is true of all previously described embodiments of the present invention in that where decoupling capacitors C are discussed as being positioned between conductive interconnects in adjacent rows then the same concepts apply equally to the positioning of the decoupling capacitors between conductive interconnects in adjacent columns. Also note that each of the previously described embodiments need not be used exclusively on a given external circuit board 300, but instead combinations of these embodiments may be utilized depending upon the pin out for the power supply plane VDD and ground plane GND and associated conductive interconnects 302. For example, decoupling capacitors C may be located around the periphery of the external circuit board 300 where conductive interconnects 302 corresponding to the power supply plane VDD and ground plane GND are located around the periphery. At the same time, the decoupling capacitors C are positioned according to any of the previously described embodiments on the interior of the external circuit board 300 where conductive interconnects 302 corresponding to the power supply plane VDD and ground plane GND are located on the interior of the external circuit board. For these interior mounted decoupling capacitors C, some may be positioned as shown in FIG. 5, others as shown in FIG. 4, and still others as shown in FIG. 3.

Although not shown in FIG. 3, the chip coupled to the external circuit board 300 includes a semiconductor die (not shown) in which electronic circuitry is formed to perform a desired function, as was previously discussed with reference to the chip 100 and semiconductor die 102 of FIG. 1. This electronic circuitry may perform any of a myriad of different functions, and thus the circuitry may be, for example, digital signal processing circuitry or microprocessor circuitry. In one embodiment, the circuitry corresponds to circuitry forming a networking switch that selectively interconnects components coupled to various ports of the networking switch.

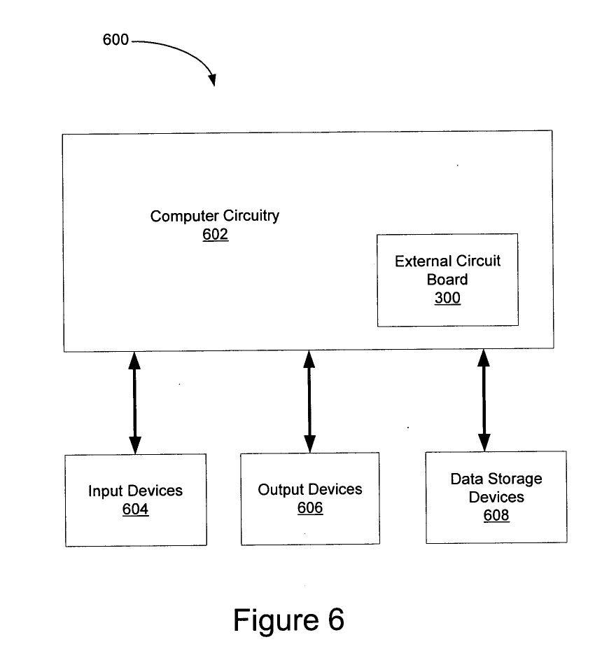

FIG. 6 is a functional block diagram of a computer system 600 including computer circuitry 602 containing the external circuit board 300 and associated chip or chips (not shown) of FIG. 3 according to another embodiment of the present invention. The computer circuitry 602 includes circuitry for performing various computing functions, such as executing specific software to perform specific calculations or tasks. In addition, the computer system 600 includes one or more input devices 604, such as a keyboard and a mouse, coupled to the computer circuitry 602 to allow an operator to interface with the computer system. Typically, the computer system 600 also includes one or more output devices 606 coupled to the computer circuitry 602, such output devices typically including a printer and a video terminal. One or more data storage devices 608 are also typically coupled to the computer circuitry 602 to store data or retrieve data from external storage media (not shown). Examples of typical data storage devices 608 include hard and floppy disks, tape cassettes, compact disk read-only (CD-ROMs) and compact disk read-write (CD-RW) memories, and digital video disks (DVDs).

Even though various embodiments and advantages of the present invention have been set forth in the foregoing description, the above disclosure is illustrative only, and changes may be made in detail and yet remain within the broad principles of the present invention. Therefore, the present invention is to be limited only by the appended claims.

What is claimed is:

1. A method of reducing a value of an inductance in series with a decoupling capacitor for a ball grid array, the ball grid array including a plurality of conductive balls coupled to conductive interconnects exposed on a surface of a circuit board, with the surface including a periphery and an interior and having conductive interconnects exposed on both the interior and the periphery, the method including physically positioning at least one decoupling capacitor adjacent conductive interconnects on the interior of the surface of the circuit board and electrically coupling each capacitor to at least two of the adjacent conductive interconnects.

2. The method of claim 1 wherein the conductive interconnects are arranged in rows and columns on the surface, each row having an axis and wherein physically positioning at least one decoupling capacitor adjacent conductive interconnects on the interior of the surface of the circuit board comprises positioning each decoupling capacitor between adjacent rows of conductive interconnects with an elongated axis of the capacitor substantially parallel to the axes defined by the adjacent rows of conductive interconnects.

3. The method of claim 2 wherein each decoupling capacitor is positioned substantially in a center of a square of,conductive interconnects defined by two interconnects in a first one of the adjacent rows and two interconnects in a second one of the adjacent rows.

4. The method of claim 1 wherein the conductive interconnects are arranged in rows and columns on the surface, each row having an axis and wherein physically positioning at least one decoupling capacitor adjacent conductive interconnects on the interior of the surface of the circuit board comprises positioning each decoupling capacitor between adjacent rows of conductive interconnects with an elongated axis of the capacitor at an angle relative to the axes defined by the adjacent rows of conductive interconnects.

5. The method of claim 4 wherein each decoupling capacitor is positioned at the angle and approximately centered between two conductive interconnects in the adjacent rows of interconnects.

6. The method of claim 4 wherein the angle is an acute angle.

7. The method of claim 1 wherein physically positioning at least one decoupling capacitor adjacent conductive interconnects on the interior of the surface of the circuit board includes attaching each capacitor to the surface of the circuit board.

8. The method of claim 7 wherein attaching each capacitor to the surface of the circuit board comprises gluing each capacitor to the surface.

9. An electronic assembly, comprising:
a die in which electronic circuitry is formed;
an interconnect board having a first surface physically attached to the die and having a second surface, the interconnect board including a plurality of conductive traces coupled to the electronic circuitry in the die and coupled to a plurality of conductive balls exposed on the second surface;
a circuit board including a plurality of conductive interconnects exposed on a surface and a plurality of conductive traces coupled to the conductive interconnects, the surface of the circuit board having a periphery and an interior with conductive interconnects exposed on both the interior and around the periphery, and each conductive interconnect being coupled to a corresponding conductive ball exposed on the second surface of the interconnect board; and
at least one decoupling capacitor, each decoupling capacitor being attached to a surface of the circuit board adjacent conductive interconnects on the interior of the surface of the circuit board and each decoupling capacitor being electrically coupled to at least two of the adjacent conductive interconnects.

10. The electronic assembly of claim 9 wherein the conductive interconnects are arranged in rows and columns on the surface, each row having an axis and each capacitor having an elongated axis, and each decoupling capacitor being attached to the surface between adjacent rows of conductive inteconnects with the elongated axis of the capacitor substantially parallel to the axes of the adjacent rows of conductive interconnects.

11. The electronic assembly of claim 10 wherein each decoupling capacitor is positioned substantially in a center of a square of conductive interconnects defined by two interconnects in a first one of the adjacent rows and two interconnects in a second one of the adjacent rows.

12. The electronic assembly of claim 9 wherein the conductive interconnects are arranged in rows and columns on the surface, each row having an axis and each capacitor having an elongated axis and wherein each decoupling capacitor is attached between adjacent rows of conductive interconnects with the elongated axis of the capacitor at an angle relative to the axes defined by the adjacent rows of conductive interconnects.

13. The electronic assembly of claim 12 wherein each decoupling capacitor is positioned at the angle and approximately centered between two conductive interconnects in the adjacent rows of interconnects.

14. The electronic assembly of claim 13 wherein the angle is an acute angle.

15. The electronic assembly of claim 14 wherein each capacitor includes electrical terminals disposed on opposite ends of opposing sides of the capacitor, with a first one of the electrical terminal being electrically coupled to a first one of the two conductive interconnects and a second one of the electrical terminals being electrically coupled to the other one of the two conductive inteconnects.

16. The electronic assembly of claim 9 wherein the electronic circuitry in the die comprises network switching circuitry.

17. The electronic assembly of claim 9 wherein the die is glued to the first surface of interconnect board to physically attach the die to the first surface.

18. The electronic assembly of claim 9 wherein the electronic circuitry in the die is coupled to the conductive traces in the interconnect board through wire bonding.

19. The electronic assembly of claim 9 wherein the electronic circuitry in the die is coupled to the conductive traces in the interconnect board through a flip-chip interconnection.

20. The electronic assembly of claim 9 wherein each decoupling capacitor comprises a multilayer ceramic capacitor.

21. A computer system, comprising:
at least one data storage device;
at least one input device;
at least one output device; and
processing circuitry coupled to the data storage, input, and output devices, the processing circuitry including an electronic assembly comprising,
a die in which electronic circuitry is formed;
an interconnect board having a first surface physically attached to the die and having a second surface, the interconnect board including a plurality of conductive traces coupled to the electronic circuitry in the die and coupled to a plurality of conductive balls exposed on the second surface;
a circuit board including a plurality of conductive interconnects exposed on a surface and a plurality of conductive traces coupled to the conductive interconnects, the surface of the circuit board having a periphery and an interior with conductive interconnects exposed on both the interior and around the periphery, and each conductive interconnect being coupled to a corresponding conductive ball exposed on the second surface of the interconnect board; and
at least one decoupling capacitor, each decoupling capacitor being attached to a surface of the circuit board adjacent conductive interconnects on the interior of the surface of the circuit board and each decoupling capacitor being electrically coupled to at least two of the adjacent conductive interconnects.

22. The computer system of claim 21 wherein the electronic circuitry in the die comprises network switching circuitry operable to couple the processing circuitry to a computer network.

23. The computer system of claim 21 wherein at least one of the storage devices comprises a magnetic disk, at least one of the input devices comprises a keyboard, and at least one of the output devices comprises a video display.
